(19) United States
(12) Patent Application Publication
(10) Pub. No.: US 2002/0084928 A1
(43) Pub. Date: Jul. 4, 2002

(54) Method and apparatus for time multiplexing of thermal sensor

(76) Inventor: William H. Nale, Livermore, CA (US)

Correspondence Address: John P. Ward, BLAKELY, SOKOLOFF, TAYLOR & ZAFMAN LLP, Seventh Floor, 12400 Wilshire Boulevard, Loa Angeles, CA, 90025-1026, US

(21) Appl. No.: 09/752,079

(22) Filed: Dec. 29, 2000

(51) Int. Cl. H03M 1/34; H03M 1/12

(52) U.S. Cl. 341/164; 341/155

(57) ABSTRACT

An apparatus for time-multiplexing a thermal sensor includes a digital-to-analog converter. The digital-to-analog converter provides an output to a comparator. The thermal sensor also provides an output to the comparator. A sequencer selects one of several input values to be applied to the digital-to-analog converter input. The sequencer further selects one of several latching devices to latch the output of the comparator. Once the result of the compare operation between the output of the thermal diode and the output of the digital-to-analog converter is latched, then the sequencer selects another one of the several input values and also selects another one of the several latching devices and another comparison is made between the output of the digital-to-analog converter and the output of the thermal sensor. The sequencer continues to select from among the several input values and corresponding latching devices in a rotating fashion.

### FIELD OF THE INVENTION

The present invention pertains to the field of computer systems. More particularly, this invention pertains to the field of thermal sensors.

### BACKGROUND OF THE INVENTION

Thermal management is an important issue in today's computer systems. In particular, it is desirable to discern the temperature of a semiconductor device and to be able to perform various functions when the semiconductor device temperature reaches various trip point temperatures.

One system for measuring semiconductor device temperature involves a software agent running on a microprocessor where the software agent manipulates the input of a digital-to-analog converter (DAC) located in a semiconductor device. The DAC output is delivered to a comparator to be compared with an output from a thermal diode, also located in the semiconductor device. If the output of the thermal diode exceeds the DAC output, the comparator trips (its output is driven to a logically high voltage level) indicating that the temperature represented by the value applied at the input of the DAC by the software agent has been exceeded. The software routine generally begins by delivering a value representing a starting temperature to the DAC. The routine continues with the software agent periodically delivering new values representing decreasing temperatures to the input of the DAC until the comparator trips.

The approach described above has the disadvantage of requiring software control and intervention. This utilizes microprocessor resources and also requires a greater amount of time to perform a temperature measurement than would otherwise be required with a hardware implementation.

Other prior systems utilize hardware implementations to monitor trip point temperatures. For example, a DAC has applied to its input a value representing a trip point. If the output of the DAC becomes less than the output of a thermal diode, a comparator trips and indicates to other circuitry to perform a power management task such as clock throttling. A second trip point may be implemented by adding an additional comparator and offsetting the output of the DAC by a fixed value. The output of the thermal diode is sent to inputs of both comparators. One trip point may be set to represent a catastrophic temperature condition and the other trip point may be set to represent a high temperature trip point. The catastrophic trip point comparator and the high temperature trip point comparator may communicate trip point conditions to various circuits to perform thermal management functions such as clock throttling and interrupt generation. This arrangement has the disadvantage of having a permanent offset between the two trip points.

Still other prior systems implement both the software managed temperature measurement routine described above as well as the hardware trip point arrangement described above. However, in these prior systems, whenever the DAC is under software control for the purposes of measuring temperature, the trip point detection circuitry is disabled. Because the software managed temperature measurement routine is time consuming, there is a protracted period of time during the software managed temperature measuring routing where there is no trip point monitoring.

### BRIEF DESCRIPTION OF THE DRAWINGS

The invention will be understood more fully from the detailed description given below and from the accompanying drawings of embodiments of the invention which, however, should not be taken to limit the invention to the specific embodiments described, but are for explanation and understanding only.

FIG. 1 is a block diagram of one embodiment of a thermometer for periodically measuring and reporting temperature within a semiconductor device.

FIG. 2 is a flow diagram of one embodiment of a method for periodically measuring and reporting temperature within a semiconductor device.

FIG. 3 is a block diagram of one embodiment of a computer system including a system logic device having a thermometer for periodically measuring temperature within a semiconductor device.

FIG. 4 is a block diagram of one embodiment of an apparatus for time multiplexing of a thermal sensor.

### DETAILED DESCRIPTION

Described below are embodiments including a thermometer that periodically measures the temperature in a semiconductor device without the requirement of software intervention. Also described below are embodiments that provide for time-multiplexing of a DAC, comparator, and thermal sensor for performing several trip point detection and temperature measuring functions.

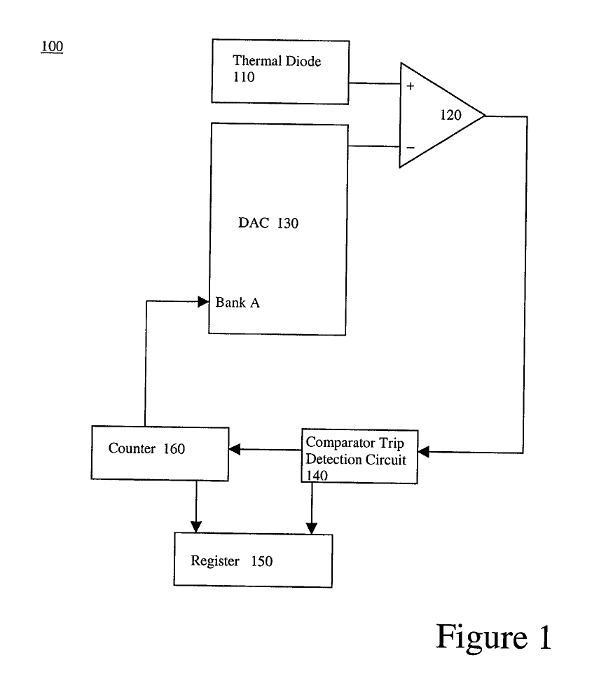

FIG. 1 is a block diagram of one embodiment of a thermometer 100 for periodically measuring and reporting temperature within a semiconductor device. The thermometer 100 includes a thermal diode 110 that delivers an output to a positive input of a comparator 120. The thermometer 100 also includes a digital-to-analog converter (DAC) 130 that provides an output to a negative input of the comparator 120.

Further included in the thermometer 100 is a counter 160. The counter 160 begins counting in this example embodiment at the value zero and increments periodically. The counter provides the counter value to the Bank A input of the DAC 130. The DAC 130 converts the digital counter value provided by the counter 160 into an analog value that is delivered to the negative input of the comparator 120.

The counter value represents a temperature. For this embodiment, the counter 160 begins to count at zero where zero represents the greatest temperature to be measured by the thermometer 100. An increase in counter value represents a decrease in temperature. Also for this example embodiment, as the value applied to the Bank A input of the DAC 130 increases, the output of the DAC 130 decreases. Other embodiments are possible where the counter begins at values other than zero or where the counter decrements instead of increments.

The comparator compares the values delivered from the thermal diode 110 and the DAC 130. If the output of the DAC 130 is greater than the output of the thermal diode 110, then the output of the comparator 120 will show a logically low voltage level indicating that the temperature represented by the counter value is less than the temperature sensed by the thermal diode 110. If the output of the DAC 130 is less than the output of the thermal diode 110, then the output of the comparator 120 will show a logically high voltage level indicating that the temperature represented by the counter value is greater than the temperature sensed by the thermal diode 110.

The output of the comparator 120 is delivered to a comparator trip detection circuit 140. If the comparator trip detection circuit 140 detects a logically high voltage level delivered by the comparator 120, then the comparator trip detection circuit 140 indicates to a register 150 to store the value of the counter 160 which was most recently presented to the Bank A input of the DAC 130. In this manner, a software agent running on a microprocessor may read the counter data from the register 150 and determine the temperature indicated by the thermometer 100.

Once the count data is stored in the register 150, the counter 160 is reset to zero and the process described above is repeated.

The thermometer 100 has the intended advantage of performing automatic temperature determination without software control or intervention. Software becomes involved only when reading the counter data from the register 150.

Although the thermometer 100 is described using a thermal diode 110 as a thermal sensor, other embodiments are possible using other circuitry capable of providing a voltage that varies with temperature.

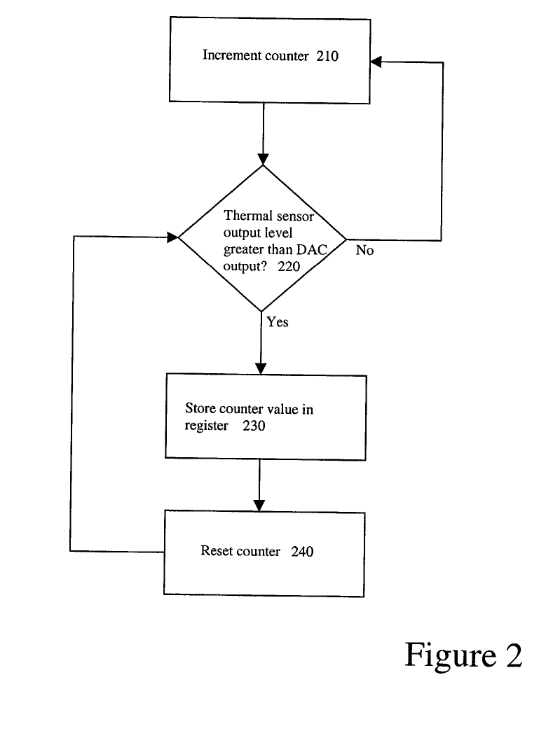

FIG. 2 is a flow diagram of one embodiment of a method for periodically measuring and reporting temperature within a semiconductor device. At block 240, a counter is reset. The counter value is delivered to a DAC and at block 220 a determination is made as to whether a thermal sensor output level is greater than the output of the DAC. If the thermal sensor output level is not greater than the output of the DAC, then at block 210 the counter is incremented.

If at block 220 it is determined that the thermal sensor output level is greater than the DAC, then at block 230 the counter value is stored in a register. The register is readable by a software agent.

Following block 230, the counter is reset at block 240 and the process described above repeats.

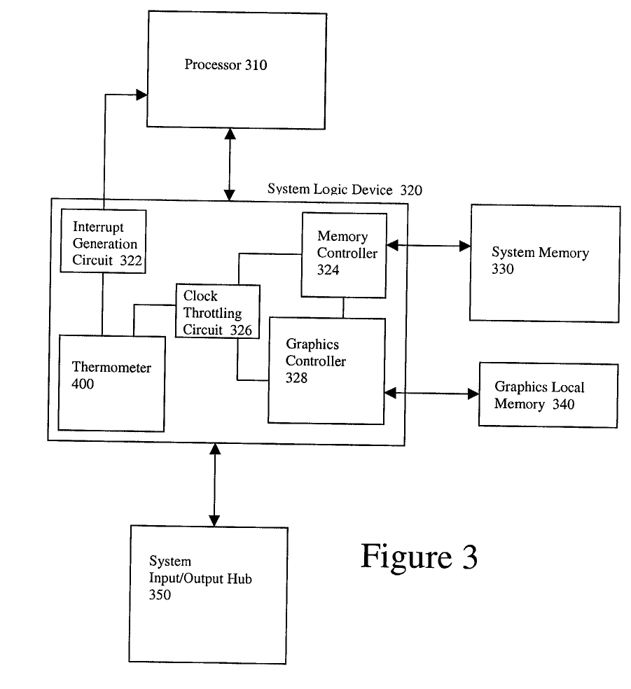

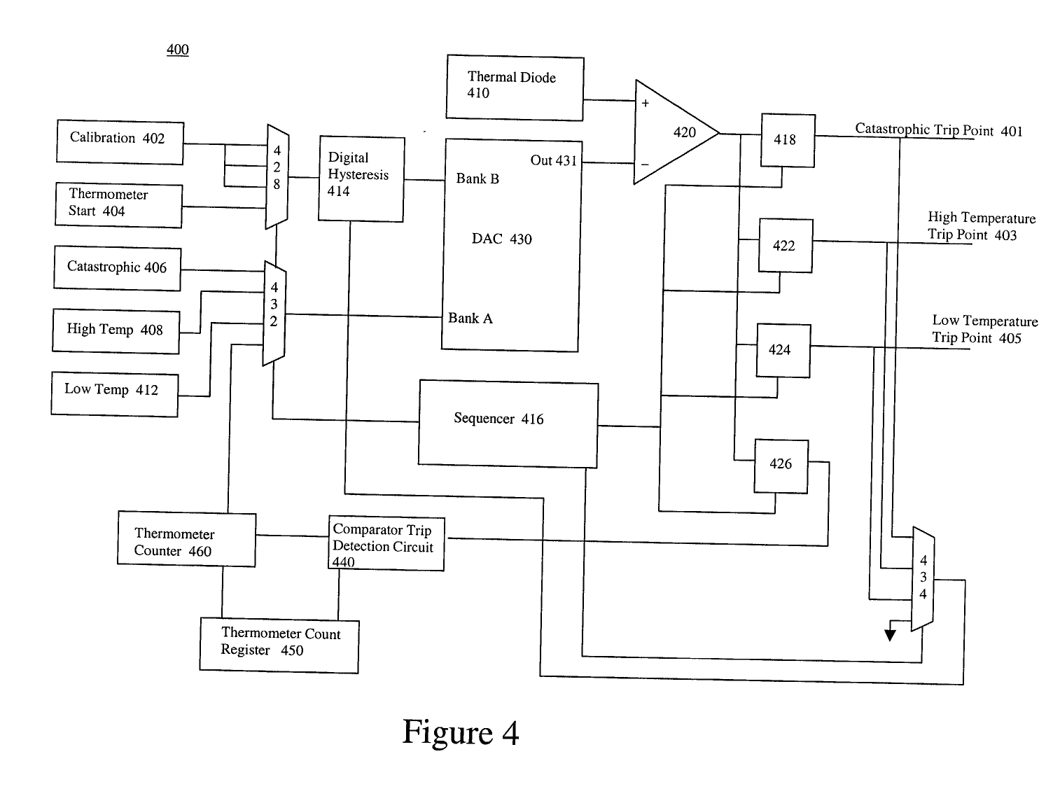

FIG. 3 is a block diagram of one embodiment of a computer system including a system logic device 320 having a thermometer 400 for periodically measuring temperature within a semiconductor device. The thermometer 400 also includes circuitry for monitoring several temperature trip points and communicating various temperature conditions to an interrupt generation circuit 322 and a clock throttling circuit 326. The thermometer 400 is discussed more fully below in connection with FIG. 4.

The system logic device 320 further includes a memory controller 324 that is coupled to a system memory 330. Also included in the system logic device 320 is a graphics controller 328 that is coupled to a graphics local memory 340. The memory controller 324 and the graphics controller 328 are additionally coupled to the clock throttling circuit 326. The system logic device 320 is also coupled to a system input/output hub 350.

FIG. 4 is a block diagram of one embodiment of the thermometer 400. The thermometer 400 includes circuitry for time multiplexing of a thermal sensor (thermal diode 410 in this example). The thermometer 400 includes a sequencer 416 that controls the time-multiplexing aspects of the remaining circuitry. The thermometer 400 in this example embodiment performs four separate functions. Three of the functions include temperature trip point monitoring functions while the fourth function is that of an automatic thermometer that operates without software control. For this example embodiment, the sequencer 416 causes the thermometer 400 to first perform a catastrophic trip point monitoring function, then a high temperature trip point monitoring function, then a low temperature trip point monitoring function, and lastly the thermometer function.

When the sequencer 416 is in the catastrophic trip point state, the sequencer 416 indicates to a multiplexor (MUX) 428 to select an input from a calibration register 402. The calibration register 402 is provided to allow for programmable compensation that may be required due to variations in the manufacturing process. The output of the MUX 428 is delivered to a bank B input of a DAC 430 through a digital hysteresis unit 414. The digital hysteresis unit 414 is discussed more fully below.

When in the catastrophic trip point state, the sequencer 416 also indicates to a MUX 432 to select an input from a catastrophic register 406. The catastrophic register 406 may be programmed with a value that represents a catastrophically high temperature. The value stored in the catastrophic register 406 is delivered to the bank A input of the DAC 430. The DAC 430 converts the digital values presented at the bank A and bank B inputs into a corresponding analog voltage that is driven on the Out 431 output. The output of the DAC 430 is delivered to a negative input of a comparator 420. A thermal diode 410 delivers a voltage corresponding to a sensed temperature to a positive input of the comparator 420. If the output of the thermal diode 410 is greater than the output of the DAC 430 (the output of the DAC 430 at this point represents a catastrophic temperature value), then the comparator 420 trips (drives a logically high voltage on its output).

The sequencer 416, while still in the catastrophic trip point state, selects a latching device 418 to latch the output of the comparator 420. The latched value is made available to other circuitry, such as the interrupt generation circuit 322 of FIG. 3, via the catastrophic trip point signal 401. The sequencer 416 further indicates to a MUX 434 to select an input from the catastrophic trip point signal 401 to be delivered to the digital hysteresis unit 414.

The sequencer 416 next moves to the high temperature trip point state. When in the high temperature trip point state, the sequencer 416 indicates to the multiplexor (MUX) 428 to again select an input from the calibration register 402. The sequencer 416 also indicates to the MUX 432 to select an input from a high temperature register 408. The high temperature register 408 may be programmed with a value that represents a temperature that, while not catastrophically high, is high enough that corrective action (perhaps clock throttling) is necessary. The value stored in the high temperature register 408 is delivered to the bank A input of the DAC 430. The DAC 430 again converts the digital values presented at the bank A and bank B inputs into a corresponding analog voltage that is driven onto the Out 431 output. If the output of the thermal diode 410 is greater than the output of the DAC 430 (the output of the DAC 430 at this point represents a high temperature value), then the comparator 420 trips (drives a logically high voltage on its output).

The sequencer 416, while still in the high temperature trip point state, selects a latching device 422 to latch the output of the comparator 420. The latched value is made available to other circuitry, such as the clock throttling circuit 326 of FIG. 3, via the high temperature trip point signal 403. The sequencer 416 further indicates to the MUX 434 to select an input from the high temperature trip point signal 403 to be delivered to the digital hysteresis unit 414.

The sequencer 416 next moves to the low temperature trip point state. When in the low temperature trip point state, the sequencer 416 indicates to the multiplexor (MUX) 428 to again select an input from the calibration register 402. The sequencer 416 also indicates to the MUX 432 to select an input from a low temperature register 412. The low temperature register 412 may be programmed with a value that represents a safe operating temperature. The value stored in the low temperature register 412 is delivered to the bank A input of the DAC 430. The DAC 430 again converts the digital values presented at the bank A and bank B inputs into a corresponding analog voltage that is driven onto the output 431. If the output of the thermal diode 410 is greater than the output of the DAC 430 (the output of the DAC 430 at this point represents a low temperature value), then the comparator 420 trips (drives a logically high voltage on its output).

The sequencer 416, while still in the low temperature trip point state, selects a latching device 424 to latch the output of the comparator 420. The latched value is made available to other circuitry, such as the clock throttling circuit 326 of FIG. 3, via the low temperature trip point signal 405. The sequencer 416 further indicates to the MUX 434 to select an input from the low temperature trip point signal 405 to be delivered to the digital hysteresis unit 414.

Finally, the sequencer 416 moves to the thermometer state. The thermometer function operates in much the same fashion as the thermometer 100 discussed above in connection with FIG. 1. A thermometer start register 404 is programmed with a value that represents a temperature at which the thermometer function will begin to check against the output of the thermal diode 410. A thermometer counter 460, initially set at zero for this embodiment, increments every time the sequencer 416 enters the thermometer state. The value stored in the thermometer start register 404 is delivered to the bank B input of the DAC 430 through the MUX 428 while the thermometer counter 460 value is delivered to the bank A input of the DAC 430 through the MUX 432.

The DAC 430 converts the combined values applied to the bank A and bank B inputs into an analog voltage that is delivered to the negative input of the comparator 420. If the output of the thermal diode 410 exceeds the output of the DAC 430, then the comparator trips. The sequencer 416 causes a latching device 426 to latch the output of the comparator 420. The output of the latching device 426 is delivered to a comparator detection circuit 440. If the comparator trip detection circuit 440 detects that the comparator 420 has tripped, then a thermometer count register 450 stores the last value output by the thermometer counter 460. The thermometer counter 460 is then reset to zero.

If the comparator trip detection circuit 440 does not detect a comparator trip, then the next time the sequencer 416 enters the thermometer state the thermometer counter 460 increments its value and the above process is repeated. Once a thermometer count value has been stored in the thermometer count register 450, that value is may be read by a software agent that can determine the temperature from the thermometer count value.

For this example embodiment, an increase in value applied to the DAC 430 inputs results in a reduction in voltage level at the DAC output. Thus, the thermometer start register 404 value represents the maximum temperature that can be checked in the current example embodiment.

For this example embodiment, the sequencer 416 changes state every 40 nS. Thus, the catastrophic, high, and low temperature trip points are checked every 160 nS. Thermometer count values are provided to the thermometer count register 450 about every 16 uS for the lowest temperatures and more often for higher temperatures.

The digital hysteresis unit 414 is provided to take care of the case where the output of the thermal diode is hovering very close to one of the trip points. For example, without the digital hysteresis, it is possible for the comparator 420 to trip during one catastrophic trip point state but 160 nS later during the next catastrophic trip point state the output of the thermal diode 410 may have dipped just below the trip point and the comparator will not trip. In this situation the value of the catastrophic trip point signal 401 would toggle in an undesirable fashion.

The digital hysteresis unit 414 solves this by adding a small amount to the value delivered by the MUX 428 during the catastrophic trip point state, the high temperature trip point state, and the low temperature trip points state if the last time those states where entered the comparator tripped. The digital hysteresis unit 414 monitors the output of a MUX 434 that receives at its inputs the catastrophic trip point signal 401, the high temperature trip point signal 403, and the low temperature trip point 405. The last input of the MUX 434 is tied to a logically low voltage level.

The sequencer 416 causes the MUX 434 to select an appropriate input to be delivered to the digital hysteresis unit 414 for each state. During the thermometer state, no digital hysteresis is applied. If during the other states, however, the appropriate corresponding trip point signal 401, 403, or 405 indicates a previous comparator trip, then digital hysteresis is applied. By increasing by a small amount the value applied to the bank B input, the voltage output from the DAC 430 is decreased by a corresponding amount. Therefore, the output of the thermal diode 410 would need to drop by more than that amount before a change of trip point status would be reflected.

The registers 404, 406, 408, and 412 may be programmable, or may contain fixed values. Other embodiments may implement at least the catastrophic register 406 with a locking mechanism to protect against software virus.

A computer system, such as that shown in FIG. 3, may make varied use of the catastrophic trip point signal 401, the high temperature trip point signal 403, and the low temperature trip point signal 405. For example, an indication that the catastrophic trip point has been reached may result in an interrupt being sent to a microprocessor which would then run an interrupt handler routine to shut down the computer system. As another example, an indication that the high temperature trip point has been reached may result in clock throttling in an effort to reduce the device temperature. Once the device cools sufficiently that the device temperature falls below the low temperature trip point, normal system operation can resume. Other embodiments are possible using these and other techniques for thermal management in computer systems.

In the foregoing specification the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than in a restrictive sense.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the invention. The various appearances of “an embodiment,” “one embodiment,” or “some embodiments” are not necessarily all referring to the same embodiments.

What is claimed is:

1. An apparatus, comprising:
a digital-to-analog converter including a first input and an output;
a comparator including a first input, and second input, and an output, the digital-to-analog converter coupled to the second comparator input;
a thermal sensor coupled to the first comparator input;
a plurality of latching devices coupled to the comparator output; and
a sequencer to select one of a plurality of input values to be applied to the first input of the digital-to-analog converter, the sequencer also to select one of the plurality of latching devices to latch the output of the comparator.

2. The apparatus of claim 1, the sequencer to select the one of the plurality of input values from the plurality of input values on a rotating basis, each of the plurality of input values applied to the digital-to-analog converter for a predetermined period of time.

3. The apparatus of claim 2, wherein the plurality of input values includes a catastrophic trip point value stored in a catastrophic trip point register.

4. The apparatus of claim 3, wherein the plurality of input values includes a high temperature trip point value stored in a high temperature trip point register.

5. The apparatus of claim 4, wherein the plurality of input values includes a low temperature trip point value stored in a low temperature trip point register.

6. The apparatus of claim 5, wherein the plurality of input values includes a thermometer counter value, the thermometer counter value generated by a thermometer counter circuit.

7. The apparatus of claim 6, the plurality of latching devices including a catastrophic trip point latching device, a high temperature trip point latching device, a low temperature trip point latching device, and a thermometer trip point latching device.

8. The apparatus of claim 7, the sequencer to select each of the plurality of latching devices according to which of the input values are applied to the digital-to-analog converter.

9. A system, comprising:
a processor; and
a system logic device coupled to the processor, the system logic device including
a clock throttling circuit,
an interrupt generation circuit, and
a time multiplexing thermal sensor circuit including
a digital-to-analog converter including a first input and an output,
a comparator including a first input, and second input, and an output, the digital-to-analog converter coupled to the second comparator input,
a thermal sensor coupled to the first comparator input,
a plurality of latching devices coupled to the comparator output, and
a sequencer to select one of a plurality of input values to be applied to the first input of the digital-to-analog converter, the sequencer also to select one of the plurality of latching devices to latch the output of the comparator.

10. The system of claim 9, the sequencer to select the one of the plurality of input values from the plurality of input values on a rotating basis, each of the plurality of input values applied to the digital-to-analog converter for a predetermined period of time.

11. The system of claim 10, wherein the plurality of input values includes a catastrophic trip point value stored in a catastrophic trip point register.

12. The system of claim 11, wherein the plurality of input values includes a high temperature trip point value stored in a high temperature trip point register.

13. The system of claim 12, the plurality of latching devices including a catastrophic trip point latching device, and a high temperature trip point latching device.

14. The system of claim 13, the sequencer to select each of the plurality of latching devices according to which of the input values are applied to the digital-to-analog converter.

15. The system of claim 14, the clock throttling circuit to throttle at least one clock signal in response to the catastrophic trip point latching device latching an output from the comparator that indicates that a catastrophic temperature has been sensed by the thermal sensor.

16. The system of claim 14, the interrupt generation circuit to signal an interrupt to the processor in response to the high temperature trip point latching device latching an output from the comparator that indicates that a high temperature has been sensed by the thermal sensor.

17. A method, comprising:
applying each of a plurality of values to an input of a digital-to-analog converter on a rotating basis;
comparing an output of the digital-to-analog converter with a temperature value delivered by a thermal sensor; and
latching a result of the compare operation in one of a plurality of latching devices.

18. The method of claim 17, wherein applying each of the plurality of values to the input of the digital-to-analog converter includes applying a catastrophic trip point value and further wherein latching the result of the compare operation in one of the plurality of latching devices includes latching the result of the compare operation in a catastrophic trip point latching device.

19. The method of claim 18, further comprising throttling a clock signal if the result latched in the catastrophic trip point latching device indicates that a catastrophic temperature has been sensed by the thermal sensor.

20. The method of claim 17, wherein applying each of the plurality of values to the input of the digital-to-analog converter includes applying a high trip point value and further wherein latching the result of the compare operation in one of the plurality of latching devices includes latching the result of the compare operation in a high temperature trip point latching device.

21. The method of claim 20, further comprising generating an interrupt if the result latched in the high temperature trip point latching device indicates that a high temperature has been sensed by the thermal sensor.
